(19) United States
(12) Patent Application Publication
(10) Pub. No.: US 2004/0112294 A1
(43) Pub. Date: Jun. 17, 2004

(54) Magnetic mirror for protection of consumable parts during plasma processing

(75) Inventors: Scott D. Allen, Wappingers Falls, NY (US); Bomy Chen, Cupertino, CA (US); David M. Dobuzinsky, New Windsor, NY (US); Richard S. Wise, New Windsor, NY (US)

Correspondence Address: INTERNATIONAL BUSINESS MACHINES CORPORATION, DEPT. 18G, BLDG. 300-482, 2070 ROUTE 52, HOPEWELL JUNCTION, NY, 12533, US

(73) Assignee: International Business Machines Corporation, Armonk, NY (US)

(21) Appl. No.: 10/729,553

(22) Filed: Dec. 5, 2003

Related U.S. Application Data
(63) Continuation-in-part of application No. 10/320,842, filed on Dec. 16, 2002.

(51) Int. Cl. C23C 16/00

(52) U.S. Cl. 118/728

(57) ABSTRACT

An apparatus for plasma processing of a wafer includes an annular structure including a magnet, where the structure is concentric with the wafer holder; the magnet generates a magnetic field for deflecting charged particles incident on the structure, thereby preventing damage to the structure by those particles. Accordingly, the structure may be of a material susceptible to erosion during the plasma processing, so that the magnetic field reduces that erosion. The cost of consumable parts in the apparatus is thus reduced. The annular structure may be characterized as a ring having a groove formed therein, with the magnet disposed in the groove. The magnet may be either a permanent magnet or an electromagnet.

### RELATED APPLICATION

This application is a continuation-in-part of U.S. application Ser. No. 10/320,842, filed Dec. 16, 2002.

### FIELD OF THE INVENTION

The present invention relates to plasma reactors for use in etching semiconductor wafers. More particularly, the present invention relates to an improved plasma etch apparatus to avoid damage to structures in the apparatus caused by the etching process.

### BACKGROUND OF THE INVENTION

Integrated circuit (IC) manufacturers must continually strive to achieve higher chip yields on a wafer for cost effective manufacturing. Today, as the industry moves to larger wafer sizes such as 300 mm, the need to increase chip yields is even more important due to the high cost of tooling. IC chip yield is affected by numerous processing steps that can damage chips. Damage can occur in many ways including damage caused by tooling design, particle contamination, wafer handling within a tool, and damage as the result of additional processing steps, such as wafer cleaning required after a given process.

One extensively used IC manufacturing process is dry etching or plasma etching which is used in the formation of structures in wafers. A plasma is a highly ionized gas containing positively and negatively charged particles (electrons and positive or negative ions) plus free radicals. The charged particles are utilized for etching in a sputtering process, which is essentially a physical etching, and the free radicals are utilized for chemical etching. Free radicals are chemically activated, electrically neutral atoms or molecules which can actively form chemical bonds when in contact with other materials, and are utilized in a plasma etching process as a reactive species which chemically combines with materials to be etched. The gas is selected so that when a plasma is formed the free radicals formed combine with the material to be etched to create a volatile compound which is removed from the system by an evacuating device. In this process, a mask is used to protect the areas that are not to be etched. Masking processes known in the art typically leave a portion of the edge of the wafer exposed to the etching gases with 1 to 3 mm exposed, depending on the type of mask used. During subsequent etch processing the edge of the wafer can be damaged directly by the etching process or indirectly by secondary reactions. The type and severity of the damage is dependent on the type of etching being performed, but the end result is damage to the wafer edge and potentially to the chips adjacent to the edge, thus reducing overall chip yield. With the high cost of tooling and wafer processing, these yield losses are becoming unacceptable.

Plasma etching damage can occur by several different methods. In some types of plasma etching, as in deep trench or micro-electromechanical (MEM) device fabrication, a hard mask material is used such as a dielectric (e.g. silicon dioxide, borosilicate glass). Etch non-uniformity across the surface of the wafer is a common problem and is caused by non-uniform process gas distribution across the wafer surface, non-uniform wafer loading at the edge of the wafer, and radially non-uniform plasma generation and wafer biasing. One solution to etch non-uniformity has been to place the wafer on a focus ring. The focus ring effectively improves etch uniformity by improving wafer loading and wafer biasing across the wafer. A major issue with this approach is that the focus ring becomes consumed, and in state of the art plasma tooling, the focus ring is typically the highest cost consumable in the plasma chamber. Modifications have been made to the focus ring design such as in U.S. Pat. No. 5,246,532 to Tomoaki Ishida, in which a permanent magnet is placed within the focus ring and a magnetic field generating means within the process chamber to repel the permanent magnet within the focus ring, causing the ring to rise to a specified height within the chamber and thus enabling the etch process to be tuned to improve uniformity. However, this does not eliminate or prevent etch damage at the wafer edge and other factors inherent in plasma etching that can affect the conditions that exist at the edge of the wafer that cause damage, nor does it prevent consumption of the focus ring during the wafer etch. For example, during silicon etch, at the edges of the wafer there is a reduced level of silicon due to the finite area of the wafer with fewer silicon etch byproducts being produced. Less protection to the silicon at the edge causes more etching of the silicon. As the plasma etch continues, the non-uniform etching at the edge results in a phenomenon known as black silicon. Black silicon is characterized by brittle, dendrite-like silicon structures. These fragile dendrites can break off and fall back onto the wafer surface, causing particle contamination. Additionally, the black silicon can form in the outer chips along the edge of the wafer, making them unusable.

There are several known ways to prevent black silicon. The first is to use a mask open tool with a cover ring to prevent the mask loss on the wafer edge. This approach prevents damage due to thinned masks but leads to severe etch non-uniformity at the wafer edge which is not corrected by the focus ring and does nothing to prevent the non-uniform etching caused by the change in mask selectivity.

A second way to reduce black silicon damage is to use a cover ring during the silicon etch process to prevent mask loss at the edge. Similarly, this method prevents etching of the wafer edge due to a thin mask at the edge, but it can block the silicon etching in the vicinity of the cover ring resulting in reduced etching or no etching at all. Additionally, when using a cover ring, the reduced silicon load moves inward from the edge of the wafer, resulting in micromasking commonly referred to as “gray silicon”.

Removal of black silicon is possible after the etch process by a well known process called bevel reactive ion etch (RIE). In bevel RIE the wafer is coated with resist and the edge of the wafer, or edge bead, is removed. An isotropic, non-selective etch is performed to remove the black silicon at the wafer edge. This approach does not prevent black silicon from forming but is a cleanup step after the etch which removes the black silicon created by the etch process. The problem with doing a cleanup after the black silicon is formed is that if there are process steps between the etch and the isotropic etch step, the black silicon dendrites can break off and redeposit onto the wafer as particle contamination.

Other well known plasma etch problems are experienced when low-k materials are incorporated into IC structures. During the etching of low-k dielectric materials “wafer arcing” between the wafer and the focus ring causes burned metal and arcing marks on the wafer edge and can extend into the chips along the edge. This plasma etch phenomenon is described in “Wafer Arcing—Etch's Secret Hurdle” Ahwming Mass., Semiconductor International, October 2002. Arcing is caused by a charging differential between the wafer and the focus ring due to differences in the charge flux. Dielectric materials on the wafer store charge differently than the quartz focus ring. Arcing causes particles to be generated within the plasma chamber which can redeposit on the wafer as particle contamination, as well as arcing burns.

Another form of wafer damage caused by the plasma etch of dielectric materials is in the form of redeposited polymeric etch byproducts on the backside of the wafer near the edge of the wafer. Although the polymer byproduct may be removed by subsequent backside cleaning or etching, these additional processes add to the already complex IC process.

Thus, there remains a need for a plasma etch apparatus that avoids the damage to semiconductor wafers that occurs during plasma etching.

### SUMMARY OF THE INVENTION

The present invention addresses the above-described need by providing an apparatus for plasma processing of a wafer that reduces the damage done by charged particles. According to the invention, there is provided a ring with a magnet disposed within the ring, the ring surrounding the wafer and proximate to the edge of the wafer. The magnetic field generated by the magnet deflects charged particles incident on the edge portion of the wafer. The magnetic field is confined to the edge portion and deflects only the charged particles that may cause damage to the wafer.

More generally, an apparatus according to the invention includes an annular structure including a magnet, where the structure is concentric with the wafer holder; the magnet generates a magnetic field for deflecting charged particles incident on the structure, thereby preventing damage to the structure by those particles. Accordingly, the structure may be of a material susceptible to erosion during the plasma processing, so that the magnetic field reduces that erosion. The annular structure may be characterized as a ring having a groove formed therein, with the magnet disposed in the groove. The magnet may be either a permanent magnet or an electromagnet.

The annular structure may be a shield ring surrounding the electrode, a guard ring surrounding the wafer holder, or a ring proximate to an interior surface of the apparatus. In the latter case the magnetic field may be effective to reduce erosion of the surface when the surface is of a material susceptible to erosion during the plasma processing.

These and other features and advantages of the invention will become apparent to those skilled in the art upon a review of the following detailed description of the presently preferred embodiments of the invention, viewed in conjunction with the appended drawings.

### BRIEF DESCRIPTION OF THE DRAWINGS

FIG. 1 is a schematic sectional view of a plasma processing apparatus which is available in the art;

FIG. 2 is a partially sectioned view of a plasma processing apparatus ring and wafer available in the art;

FIG. 3 is a perspective view of an embodiment of the present invention;

FIG. 4a is a partially sectioned view according to an embodiment of the present invention;

FIG. 4a is a partially sectioned view according to another embodiment of the present invention;

FIG. 5 is a perspective view according to an embodiment of the present invention;

FIG. 6 is a cross-sectional view of a plasma processing chamber having a ring structure including a magnetic mirror, according to an embodiment of the invention;

FIG. 7 is a cross-sectional view of a plasma processing chamber having another ring structure including a magnetic mirror, according to another embodiment of the invention;

FIG. 8 is a cross-sectional view of a plasma processing chamber having another ring structure including a magnetic mirror, according to a further embodiment of the invention;

FIG. 9 is a cross-sectional view of a plasma processing chamber having another ring structure including a magnetic mirror, according to a still further embodiment of the invention.

### DETAILED DESCRIPTION OF PREFERRED EMBODIMENTS

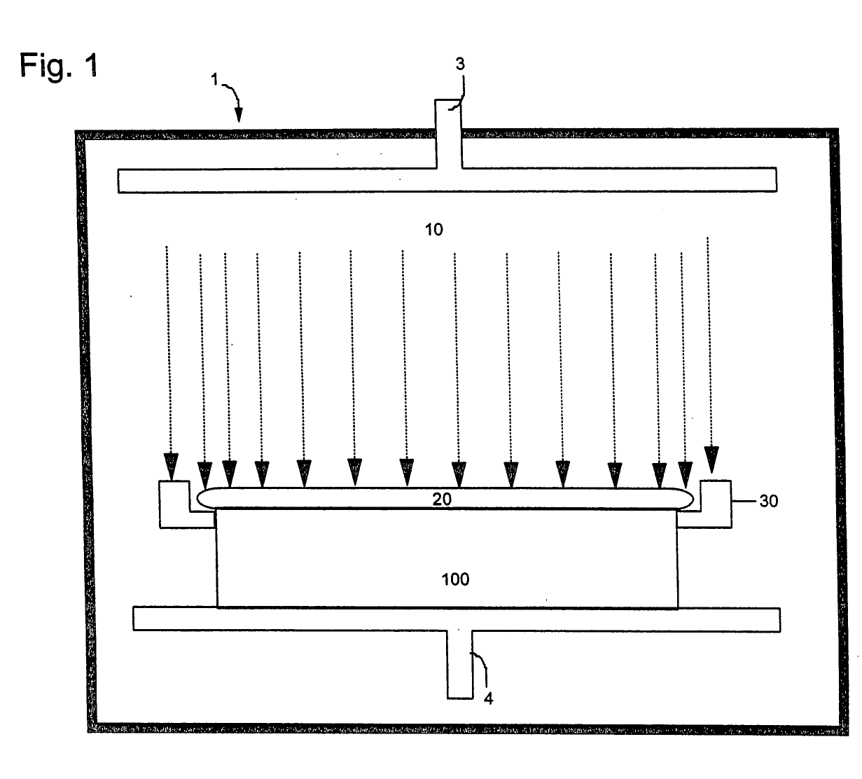

Referring now to the drawings and more particularly to FIG. 1, a cross-sectional schematic of a conventional plasma processing chamber 1 is shown. During the plasma etch process, a wafer 20 is placed on ring 30 which sits on a wafer holder 100 (wafer holder 100 typically includes an electro-static chuck). During plasma etching, charged particles 10 are generated by the electrodes 3 and 4. Further details of plasma processing chamber and plasma processing are well known in the art and are not included except where necessary to describe the present invention.

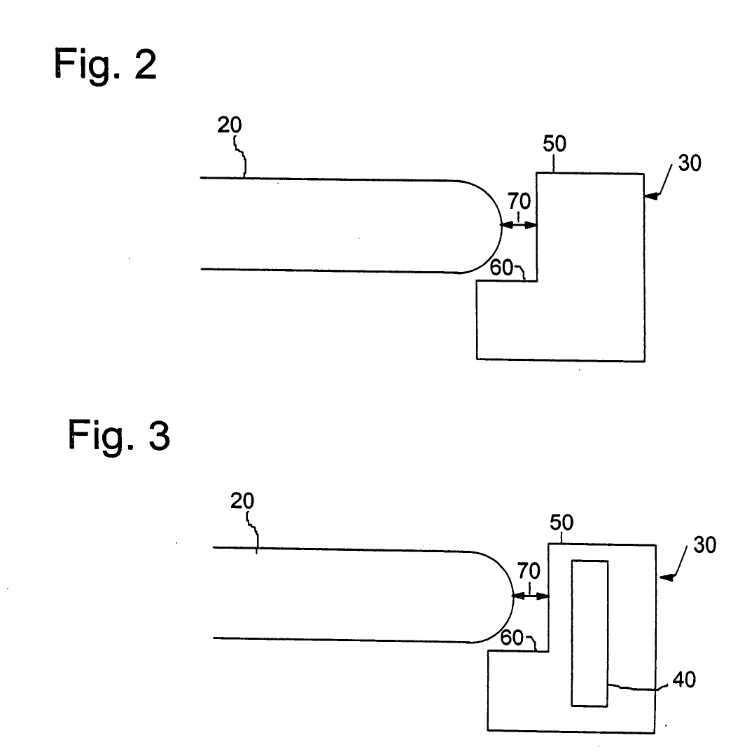

The ring 30 may also be used as a focus ring which is well known in the art to focus the charged particles onto the surface of the wafer to enhance the uniformity of the etch process across the surface of the wafer and particularly at the edge of the wafer. The ring is generally made of quartz but other materials may be used such as silicon, Y₂O₃, silicon carbide, Al₂O₃ or any suitable material that is compatible with plasma etch processing and are well known in the art. In a cross-sectional view of the ring (FIG. 2), the ring has an upper surface 50 and a lower surface 60 which underlies wafer 20 so that the edge portion of the wafer rests on surface 60 during the plasma processing. A gap 70 between the wafer and ring is approximately 500 μm to minimize scratching of the wafer during loading and unloading of the wafer onto the ring.

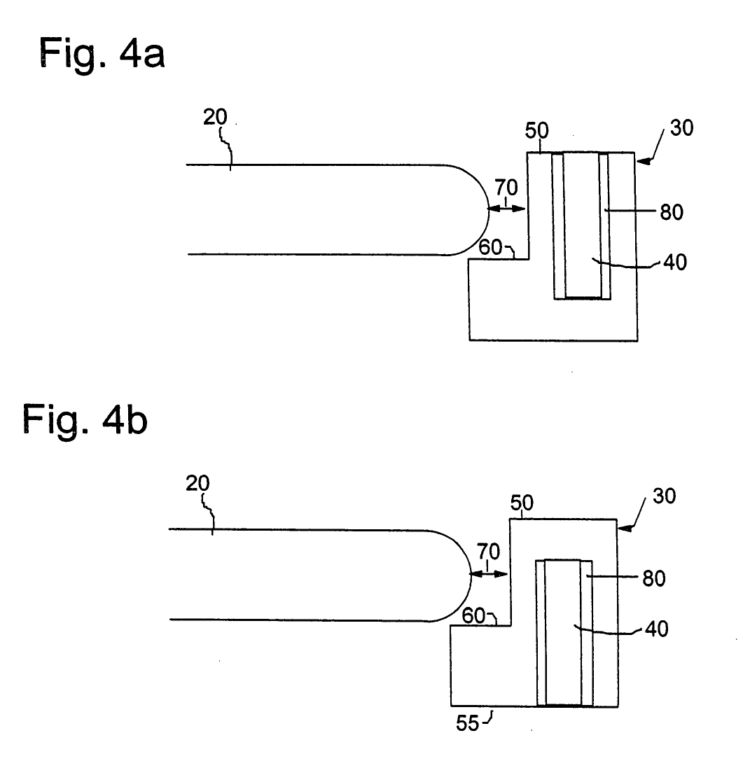

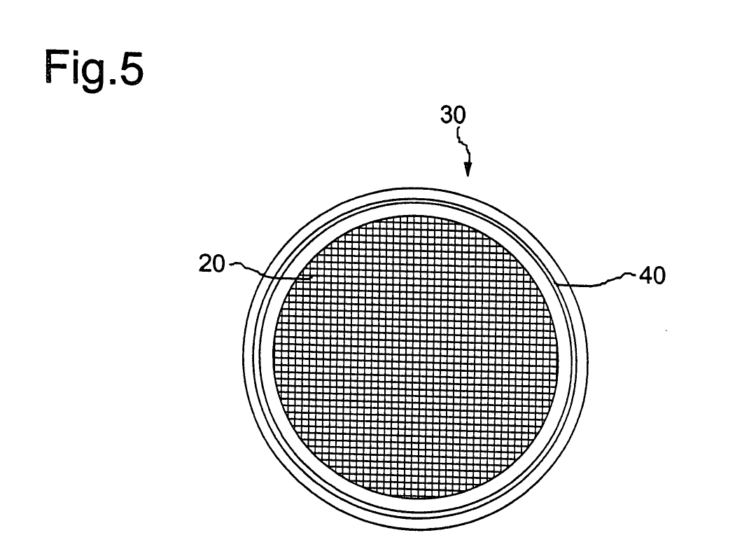

FIG. 3 illustrates, in cross-section, a first embodiment of the invention. A permanent magnet 40 is embedded in the ring. Generally, it is preferred to have the magnet embedded within the ring to keep magnetic materials away from the plasma. The magnet may be also placed in a groove or channel 80 formed in the ring on either upper surface 50 (FIG. 4a) or bottom surface 55 (FIG. 4b) as one circular magnet or several pieces of magnet, provided that the magnet pieces form a complete circle. Placing the magnet in a groove or channel structure facilitates disassembly of the ring for repair, cleaning or replacement purposes. To further illustrate the ring structure with the magnet encircling the ring, FIG. 5 shows a top down view of the ring 30 with magnet 40. Wafer 20 is placed on ring 30.

Now turning to the properties of the magnet, the optimal magnetic field strength is determined by the gyroradius of electrons being shorter than the distance to the wafer edge, effectively reflecting all electrons below a cutoff energy away from the wafer edge. In this embodiment, the ring is designed to reflect the charged particles away from the edge of the wafer.

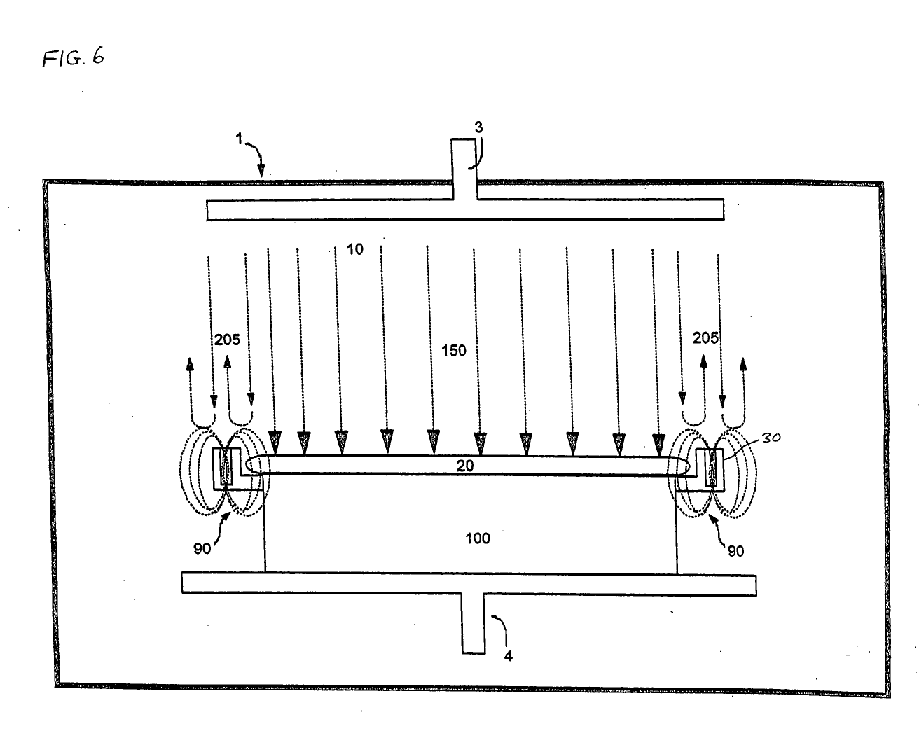

As shown in FIG. 6, during the plasma etch process, the charged particle path 150 is normal to the wafer. The magnetic field 90 has lines of magnetic flux which form loops above and below the wafer surface near its edge, and intersect the wafer. It will be appreciated that this magnetic field arrangement serves as a magnetic mirror for deflecting charged particles traveling in a vertical path and incident on the edge of the wafer. As the particles approach the area of the magnetic field 90, the particles are deflected in a path, 205, in a manner such that the etching properties of the charged particles do not affect the edge of the wafer where the magnetic field is present. The position of the magnet relative to the wafer edge is determined by the magnetic field intensity of the magnet and its desired effect on the charged ions in a given plasma process. The magnetic field intensity should decrease rapidly with distance from the edge of the wafer so as not to affect the etching process more than approximately 3 mm from the edge of the wafer. For example, for an plasma etch process to etch deep trenches in silicon, the majority of plasma electrons exist at energies in the 1-5 eV range. Choosing 20 eV for a maximum electron energy exclusion to ensure that electrons in this energy range are deflected would require a magnetic field intensity of 13.7G, 1 cm from the wafer edge, to reflect all electrons at this energy or lower. A stronger magnetic field strength intensity may be required when the plasma power is higher since under such conditions there will be higher energy particles.

The magnetic field 90 also serves to deflect charged particles from the ring structure 30. This reduces ring corrosion caused by the charged particles and extends the useful life of the ring and minimizes cost of operation of plasma etching.

A magnet may advantageously be embedded in other structures, elsewhere in the plasma processing chamber, to prevent charged particle bombardment and thus extend the useful life of those structures. In particular, if a structure is of a consumable material, the magnetic field will reduce costs associated with the structure (maintaining parts inventory, equipment downtime for parts replacement, etc.). Even if the material is not sensitive to the etch process (e.g., quartz in a reactor for etching silicon), the material is subject to corrosion, primarily by ion bombardment.

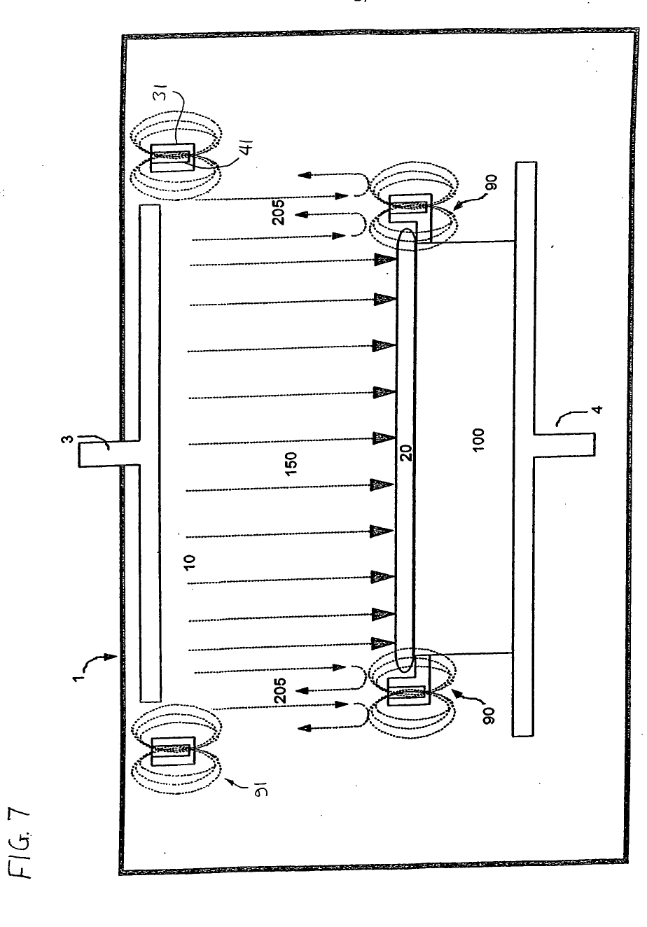

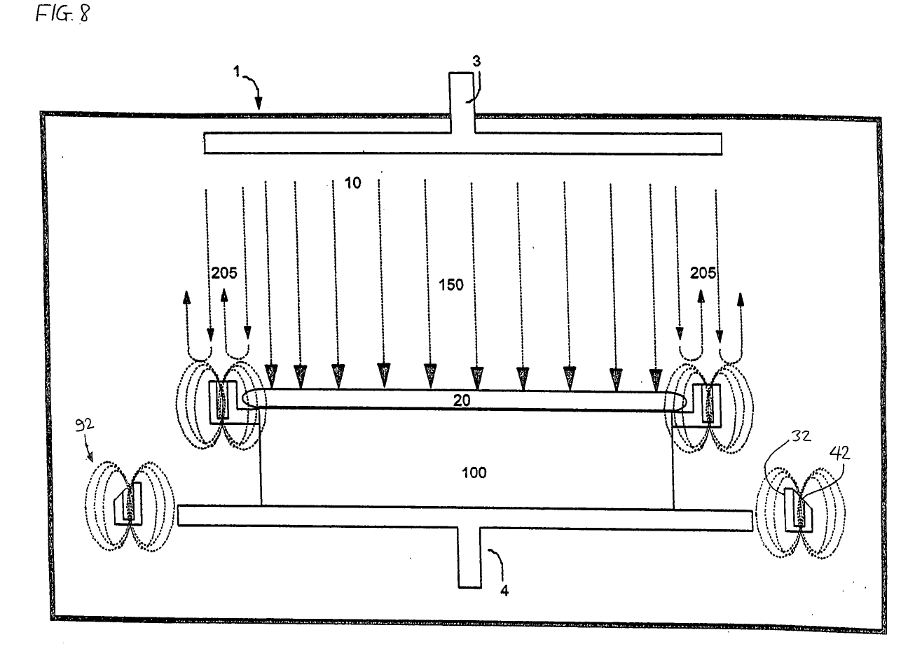

FIG. 7 shows another embodiment of the invention in which a shield ring 31 surrounds electrode 3. (A shield ring of silicon, for example, may be used in an oxide etch process.) A permanent magnet 41 is embedded in the ring and generates magnetic field 91. Field 91 serves to mitigate ion bombardment damage to the ring. If the shield ring is of a consumable material, the magnet 41 is advantageously in a groove (see FIGS. 4a and 4b), so that the magnet may be easily removed and transferred to another ring when replacement of the ring becomes necessary.

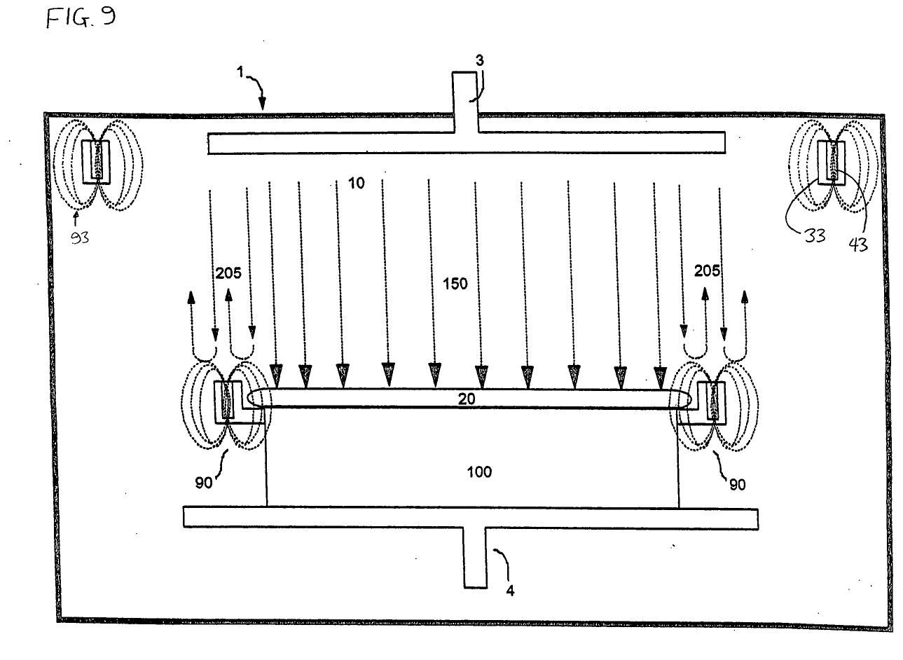

FIG. 8 illustrates another embodiment in which a guard ring 32 surrounds wafer holder 100 and electrode 4; permanent magnet 42 is embedded in the ring and generates magnetic field 92. The magnetic field serves to prevent damage to the ring, significantly extending its useful life.

FIG. 9 illustrates a further embodiment in which a ring 33 is mounted close to the roof of chamber 1. A permanent magnet 43 is embedded in the ring, generating a magnetic field 93 which protects both the ring and the chamber roof from charged particle bombardment, thereby reducing the erosion rate thereof. This may permit the roof itself to be made of a consumable material (e.g. silicon).

It will be appreciated that a magnetic mirror may be used in or around a variety of other structures inside the plasma processing chamber (e.g. the wafer chuck, confinement ring, baffle plate or gas distribution plate), depending on the design of the particular chamber, to protect those structures from charged particle bombardment and thereby reduce the cost of consumable items in the chamber.

In alternative embodiments of the invention, an electromagnet is used and can be turned on during the etch process. An electromagnet allows for tunability of the magnetic field intensity during the etch. When the magnet is used in focus ring 30, this will permit additional control and optimization of the etch process. For example, magnetic deflection of particles near the wafer edge may be desired only during certain times in the etch process, or only during certain types of processes. It will be appreciated that an electromagnet may be used in any of the ring structures described above.

While the present invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

We claim:

1. An apparatus for plasma processing of a wafer, the wafer being disposed on a wafer holder during processing, the apparatus comprising:
an annular structure including a magnet, the structure concentric with the wafer holder, the magnet generating a magnetic field for deflecting charged particles incident on the structure, thereby preventing damage to the structure by said particles.

2. An apparatus according to claim 1, wherein the magnet comprises a magnetic material embedded in said structure.

3. An apparatus according to claim 1, wherein said annular structure is characterized as a ring, the ring having a groove formed therein, and the magnet is disposed in the groove.

4. An apparatus according to claim 1, wherein the magnet is a permanent magnet.

5. An apparatus according to claim 1, wherein the magnet is an electromagnet.

6. An apparatus according to claim 1, wherein said structure is of a material susceptible to erosion during the plasma processing, so that the magnetic field reduces said erosion.

7. An apparatus according to claim 1, wherein said structure is of a material selected from the group consisting of quartz, silicon, Y₂O₃, silicon carbide and Al₂O₃.

8. An apparatus according to claim 1, wherein the apparatus includes an electrode opposite the wafer holder, said annular structure is characterized as a ring, and the ring is a shield ring surrounding the electrode.

9. An apparatus according to claim 1, wherein said annular structure is characterized as a ring, and the ring is a guard ring surrounding the wafer holder.

10. An apparatus according to claim 1, wherein said annular structure is characterized as a ring, and the ring is disposed proximate to an interior surface of the apparatus, so that the magnetic field is effective to deflect charged particles incident on said surface.

11. An apparatus according to claim 10, wherein said surface is of a material susceptible to erosion during the plasma processing, so that the magnetic field reduces said erosion.

12. An apparatus for plasma processing of a wafer, comprising:
a wafer holder;
an electrode opposite the wafer holder; and
at least one of a shield ring surrounding the electrode, a guard ring surrounding the wafer holder, and a ring proximate to an interior surface of the apparatus, including a magnet generating a magnetic field for deflecting charged particles incident on the ring, thereby preventing damage to the ring by said particles.

13. An apparatus according to claim 12, wherein the magnet comprises a magnetic material embedded in the ring.

14. An apparatus according to claim 12, wherein the ring has a groove formed therein, and the magnet is disposed in the groove.

15. An apparatus according to claim 12, wherein the magnet is a permanent magnet.

16. An apparatus according to claim 12, wherein the magnet is an electromagnet.

17. An apparatus according to claim 12, wherein the ring is of a material susceptible to erosion during the plasma processing, so that the magnetic field reduces said erosion.

18. An apparatus according to claim 12, wherein the apparatus comprises a ring proximate to an interior surface of the apparatus, and said surface is of a material susceptible to erosion during the plasma processing, so that the magnetic field reduces said erosion.
